(19) United States
(12) Patent Application Publication
(10) Pub. No.: US 2026/0223747 A1
(43) Pub. Date: Jul. 30, 2026

(54) POWER SEMICONDUCTOR MODULE

(71) Applicants: Dynex Semiconductor Limited, Lincoln (GB); Zhuzhou CRRC Times Semiconductor Co. Ltd, Zhuzhou, Hunan (CN)

(72) Inventors: Robin Adam SIMPSON, Lincoln (GB); Michael David NICHOLSON, Lincoln (GB)

(21) Appl. No.: 19/141,709

(22) PCT Filed: Dec. 22, 2022
(86) PCT No.: PCT/EP2022/087467

§ 371 Date: Jun. 20, 2025

(51) Int. Cl. H10W 90/22; H05K 1/02; H05K 1/11; H05K 1/181; H05K 3/32; H10D 80/20; H10W 40/20; H10W 70/05; H10W 70/65; H10W 70/652; H10W 80/00; H10W 90/00; H10W 90/10; H10W 90/20

(52) U.S. Cl. CPC H10W 90/22; H05K 1/0277; H05K 1/115; H05K 1/181; H05K 3/32; H10D 80/251; H10W 40/235; H10W 70/093; H10W 70/652; H10W 70/658; H10W 80/314; H10W 90/10; H10W 90/288; H10W 90/401; H10W 90/794; H05K 2201/10166; H05K 2201/10545

(57) ABSTRACT

There is provide a power semiconductor module comprising: a first substrate; a second substrate; a circuit board arranged between the first and second substrates; a first power semiconductor device T1, T2 comprising first and second power electrodes and arranged between the circuit board and the first substrate; and a second power semiconductor device T3, T4 comprising third and fourth power electrodes and arranged between the circuit board and the second substrate. The circuit board comprises a plurality of electrically conductive layers stacked with a plurality of electrically insulating layers along a stacking direction Z. At least one of the electrically insulating layers is arranged between adjacent ones of the electrically conductive layers. The plurality of electrically conductive layers comprises first, second and third electrically conductive layers which are spaced apart from one another along the stacking direction Z.

### TECHNICAL FIELD

This disclosure relates to a power semiconductor module and a method of manufacturing the same. More particularly, but not exclusively, this disclosure relates to a double-side cooled power semiconductor module which uses a multi-layer circuit board to realise interconnections between power semiconductor devices and substrates of the module.

### BACKGROUND

Wide bandgap (WBG) power semiconductor devices such as Gallium-Nitride High-electron-mobility transistors (GaN HEMTs) are capable of switching with faster slew rates than traditional silicon-based power semiconductor devices, such as metal-oxide-semiconductor field-effect transistors (MOSFETs). Energy loss during a switching transition is directly related to the time duration of the transition. Therefore, the ability to switch with faster slew rates leads to a reduction in switching energy loss and is a key advantage of power semiconductor devices made from WBG materials rather than silicon.

Traditional power modules, used for packaging silicon-based power semiconductor devices, are manufactured using patterned copper-clad ceramic substrates with wire-bonded interconnections between the copper tracks on the substrate and the chips. This technology is mature, flexible and suitable for mass production but brings with it a number of issues. First, the wire bonds have high inductances due to their relatively small cross-sectional area and sub-optimal shape. Second, the two-dimensional nature of the patterned copper on the substrate limits the capability of the designer to minimise inductances by forcing the use of indirect paths. Third, magnetic flux cancellation techniques, such as closely coupling conductors with opposing current flow directions, are difficult to achieve due to the looping shape of the bond wires. It is almost impossible to closely couple bond wires with opposing current flow directions.

High inductances are incompatible with switching at the faster slew rates enabled by WBG semiconductor devices. During turn-off of the device, a voltage overshoot above a DC supply voltage is generated across the module. The magnitude of the voltage overshoot is determined by the product of the current slew rate (dl/dt) and the stray inductance of the module. The voltage overshoot has two effects: (1) it increases switching losses by increasing the V*I product during the switching transition, (2) in extreme cases, it may lead to destruction of the power semiconductor device by exceeding its breakdown voltage.

Since wire bonds have high inductances, wire-bonded power module designs limit the maximum performance of WBG-based power semiconductor modules. To extract the ultimate performance of WBG semiconductor devices, packaging designs with reduced inductances are required.

High switching speeds also interact with parasitic capacitances and inductances to cause electromagnetic interference (EMI). High dV/dt transients interact with parasitic capacitances to produce displacement currents. High dl/dt transients interact with parasitic inductances to produce fluctuations in voltages. Current loops can cause radiated EMI. To minimise EMI, physical current loop sizes should be as small as possible, parasitic inductances should be minimised and balanced in the case of a configuration with both DC+ and DC− buses.

FIG. 1 schematically illustrates a half-bridge circuit structure 1000 with parasitic capacitances. The half-bridge structure includes a high-side power switch 1100 and a low-side power switch 1200 connected in series between a DC+ terminal and a DC− terminal. An output AC terminal is connected to a switching node between the high-side power switch and the low-side power switch. In use, the DC+, DC− and AC terminals are typically connected to conductive regions formed on an upper copper layer of a patterned copper-clad ceramic substrate. A lower copper layer of the substrate, separated from the upper copper layer by a ceramic layer, is typically connected to a ground terminal GND. Preferably, to minimise EMI, the parasitic capacitance CAc between regions of the AC potential and GND should be minimised, while parasitic capacitance between DC+ and DC− (not shown in FIG. 1) should be maximised, with DC+ to ground and DC− to ground parasitic capacitances C_{DC+}, C_{DC-} being maximised and balanced. Traditional module designs using wire bonds have high inductances in the interconnections and lack the flexibility to enable these EMI mitigation steps.

It is an object of the present disclosure, among others, to provide an improved power semiconductor module that solves problems associated with conventional power semiconductor modules, whether identified herein or otherwise.

### SUMMARY

According to a first aspect of this disclosure there is provided a power semiconductor module comprising: a first substrate; a second substrate; a circuit board arranged between the first and second substrates; a first power semiconductor device comprising first and second power electrodes and arranged between the circuit board and the first substrate; and a second power semiconductor device comprising third and fourth power electrodes and arranged between the circuit board and the second substrate; wherein: the circuit board comprises a plurality of electrically conductive layers stacked with a plurality of electrically insulating layers along a stacking direction; at least one of the electrically insulating layers is arranged between adjacent ones of the electrically conductive layers; and the plurality of electrically conductive layers comprises first, second and third electrically conductive layers which are spaced apart from one another along the stacking direction; and wherein: the first power electrode is electrically connected to the first electrically conductive layer; the second and third power electrodes are both electrically connected to the third electrically conductive layer; and the fourth power electrode is electrically connected to the second electrically conductive layer.

Within the present disclosure, the term “electrically connected” describes a permanent low-ohmic connection between electrically connected elements, for example a direct contact between the concerned elements or a low-ohmic connection via metal conductor(s).

Advantageously, the multi-layer circuit board is used to make the electrical interconnections between the first and second power semiconductor devices (thereby realising a half-bridge circuit structure or the like). Power current loops of the circuit structure are contained primarily or solely within the electrically conductive layers of the circuit board, and have a minimised vertical dimension along the stacking direction. Further by arranging the first and second power semiconductor devices at opposite sides of the circuit board, lateral dimensions of the power current loops are halved as compared to mounting both power semiconductor devices on the same substrate (as commonly seen in conventional wire-bonded modules). Thus, the physical sizes of the power current loops are significantly reduced as compared to conventional wire-bonded modules. Further, the distances between adjacent electrically conductive layers along the stacking direction are very short (e.g., a thickness of one or more electrically insulating layers, in the order of tens of micrometres). Thus, electrically conductive layers with opposing current flow directions can be closely coupled to cancel magnetic flux generated by the current flows, thereby reducing parasitic inductances of the electrical interconnections within the circuit structure.

By reducing the physical sizes of the power current loops and reducing the parasitic inductances of the electrical interconnections, radiated EMI caused by operation of the module is significantly reduced. Reducing the parasitic inductances of the electrical interconnections is also useful for reducing voltage fluctuations in the power semiconductor module, and for reducing the magnitude of voltage overshoot above a DC supply voltage of the power semiconductor module.

It would be understood that the first/second power semiconductor device may comprise more than one power semiconductor die which are electrically connected together in any suitable manner (e.g., in series or in parallel).

By having first and second substrates, the power semiconductor module may be a double-side cooled module.

The stacking direction may be generally perpendicular to a surface of the first/second substrate.

The circuit board may comprise one or more through-layer vias which selectively connect different ones of the plurality of electrically conductive layers.

The second electrically conductive layer may be arranged between the first and third electrically conductive layers.

With the defined electrical connections, it would be understood that the third electrically conductive layer may be electrically connected to a switching AC node of a half-bridge circuit structure, and that the first and second electrically conductive layers may be electrically connected to a DC positive node and a DC negative node of the half-bridge circuit structure (or vice versa), respectively. By arranging the second electrically conductive layer to be between the first and third electrically conductive layers, the first conductive layer (which may be connected to a more sensitive DC node depending upon system requirements) is shielded from electromagnetic emissions from the third electrically conductive layer. This is beneficial for reducing noises on the first conductive layer (hence the sensitive DC node), thereby improving the performance of the power semiconductor module or an upper-level power electronics system which uses the power semiconductor module.

In addition, by arranging the second electrically conductive layer to be between the first and third electrically conductive layers, the first and second electrically conductive layers can be arranged in close proximity. This arrangement is useful for closely coupling the current flows through the first and second electrically conductive layers (which may be in opposite directions), thereby reducing parasitic inductances of the electrical interconnections within the circuit structure. This arrangement is also useful for maximising the parasitic capacitance between the first and second electrically conductive layers (e.g., the parasitic capacitance between the DC positive node and the DC negative node of the half-bridge circuit structure), and thus useful for reducing line voltage ripples caused by high speed current transients produced by operation of the module.

The first power semiconductor device may be configured to block a voltage with a higher potential at the second power electrode than at the first power electrode.

The second power semiconductor device may be configured to block a voltage with a higher potential at the fourth power electrode than at the third power electrode. One or more of the first and second power semiconductor devices may be a uni-directional power semiconductor device. The term “uni-directional” means that the device blocks voltage and conducts current in the same direction.

The first/second power semiconductor device may comprise one or more of a power MOSFET, an IGBT, a WBG power semiconductor device, and/or a power diode, etc.

The first and second electrically conductive layers may be separated by a single electrically insulating layer.

The first substrate may comprise a first electrically insulating body and a first patterned electrically conductive layer arranged on a surface of the first electrically insulating body that faces the circuit board. The second substrate may comprise a second electrically insulating body and a second patterned electrically conductive layer arranged on a surface of the second electrically insulating body that faces the circuit board. The first patterned electrically conductive layer may comprise a first conductive track electrically connected to the first electrically conductive layer. The second patterned electrically conductive layer may comprise a second conductive track electrically connected to the second electrically conductive layer. One of the first and second patterned electrically conductive layers may further comprise a third conductive track electrically connected to the third electrically conductive layer.

By arranging the first and second conductive tracks at opposite sides of the circuit board, the power current paths from the first conductive track to the third conductive track and from the second conductive track to the third conductive track are generally symmetrised, This arrangement provides balanced parasitic inductances from DC+ to AC and from AC to DC− of the circuit structure. Balancing parasitic inductances is useful for minimising electromagnetic emissions from the third electrically conductive layer because imbalance cause differential currents and therefore EMI.

The first/second power semiconductor device may be mounted on the first/second patterned electrically conductive layer, respectively.

It would be understood that the electrically insulating bodies are thermally conductive, and that the third conductive track is spaced apart from the respective first or second conductive track in the same patterned electrically conductive layer.

The power semiconductor module may further comprise first, second and third power terminals electrically connected to the first, second and third conductive tracks, respectively.

The first, second and third power terminals may be directly mounted on the first, second and third conductive tracks, respectively.

In other words, the first, second and third power terminals may be arranged between the respective substrate and the circuit board.

With the expression “directly mounted”, it is meant that no other structure is between the power terminals and the conductive tracks (except a small amount of bonding material used). The first, second and third power terminals may be directly mounted on the conductive tracks by sintering, soldering or bonding by conductive epoxy resin.

Advantageously, directly mounting the power terminals on the conductive tracks improves cooling of the power terminals, which is critical for reliability of the module (e.g., joints to the power terminals and surrounding dielectric encapsulation). This is particularly important if the first/second power semiconductor device uses wide bandgap chips, since wide bandgap chips have higher current densities and higher heat flux densities than traditional silicon chips.

The power semiconductor module may comprise an encapsulant encapsulating the first and second power semiconductor devices and spaces between the circuit board and each of the first and second substrates. At least a part of each of the first, second and third power terminals may be exposed to an exterior of the power semiconductor module (by for example protruding beyond the encapsulant).

The first and second power terminals may be DC input terminals, and the third power terminal may be an AC output terminal.

The first and second conductive tracks may have approximately the same area on the respective electrically insulating body.

Advantageously, this arrangement is useful for balancing parasitic capacitances from DC+ node to ground and from DC− node to ground. Balanced capacitances to ground are useful for minimising differential currents that are a cause of EMI.

The first and second power electrodes may be both arranged on a surface of the first power semiconductor device that faces the circuit board; and/or the third and fourth power electrodes may be both arranged on a surface of the second power semiconductor device that faces the circuit board.

In other words, the first/second power semiconductor device may be lateral devices.

The use of lateral devices means that the power current loops of a circuit structure realised by the power semiconductor module are contained within the circuit board and the conductive regions (close to the top surface) of the lateral devices. As compared to the use of vertical devices (where power electrodes are arranged on opposite surfaces of the device), using lateral devices is beneficial for improving the effectiveness of magnetic flux cancellation. This is because the distance between conductors of opposing current flow directions can be kept at a relatively short level and is not opened up by the thickness of the first/second power semiconductor device.

The plurality of electrically conductive layers may further comprise fourth and fifth electrically conductive layers which are spaced apart from one another along the stacking direction. The fourth electrically conductive layer may be electrically connected to a first through-layer via of the circuit board, which may be further electrically connected to the first electrically conductive layer. The fifth electrically conductive layer may be electrically connected to a second through-layer via of the circuit board, which may be further electrically connected to the second electrically conductive layer.

Advantageously, the power circuit current of the power semiconductor module is carried in more than one layer of the circuit board. This is useful for increasing conductor cross-sectional area and reducing the overall electrical resistance and inductance of the electrical interconnections between the first and second power semiconductor devices and the substrate.

The third electrically conductive layer may be arranged between the second and fifth electrically conductive layers, which are further arranged between the first and fourth electrically conductive layers.

Advantageously, external environment (where other sensitive circuitry may be located) is shielded from electromagnetic emissions from the third electrically conductive layer.

The plurality of electrically conductive layers may further comprise a sixth electrically conductive layer which is electrically connected to a third through-layer via of the circuit board, and the third through-layer via may be further electrically connected to the third electrically conductive layer.

The third and sixth electrically conductive layers may be arranged between the second and fifth electrically conductive layers.

The first patterned electrically conductive layer may comprise fourth and fifth conductive tracks which are spaced apart from one another. The power semiconductor module may comprise fourth and fifth control terminals electrically connected to the fourth and fifth conductive tracks, respectively.

The first power semiconductor device may comprise a first control electrode configured to switch a power current flowing between the first power electrode and the second power electrode.

The plurality of electrically conductive layers may further comprise seventh and eighth electrically conductive layers which are spaced apart from one another along the stacking direction. The first control electrode may be electrically connected to the seventh electrically conductive layer, which may be further electrically connected to the fourth conductive track. The first power electrode may be electrically connected to the eighth electrically conductive layer, which may be further electrically connected to the fifth conductive track.

The seventh and eighth electrically conductive layers may be separated by a single electrically conductive layer. Advantageously, this arrangement allows the seventh and eighth electrically conductive layers to be closely coupled, thereby promoting flux cancellation and a reduction of parasitic inductances of electrical interconnections in the control circuit of the power semiconductor module. The reduced parasitic inductances improve the switching speed of the first power semiconductor device, and also reduce the risks of falsely triggering the first power semiconductor device.

Alternatively, the plurality of electrically conductive layers may further comprise a seventh electrically conductive layer which is patterned to form two or more conductive tracks, the two or more conductive tracks being spaced apart from one another. The first control electrode may be electrically connected to one conductive track of the seventh electrically conductive layer, which may be further electrically connected to the fourth conductive track. The first power electrode may be electrically connected to another conductive track of the seventh electrically conductive layer, which may be further electrically connected to the fifth conductive track.

The first and second electrically conductive layers may be arranged between the third electrically conductive layer and the seventh electrically conductive layer.

Advantageously, the control circuit of the first power semiconductor device, which is a sensitive element of the power semiconductor module, is shielded from EMI caused by high-speed electrical transients in the third electrically conductive layer.

The seventh (and/or eighth) electrically conductive layer may be arranged between the first substrate and each of the first, second and third electrically conductive layers.

The first and second electrically conductive layers may be arranged between the third electrically conductive layer, on the one hand, and the seventh and eighth electrically conductive layers, on the other hand.

The above optional features similarly apply to the second power semiconductor device: the second patterned electrically conductive layer may comprise sixth and seventh conductive tracks which are spaced apart from one another. The power semiconductor module may comprises sixth and seventh control terminals electrically connected to the sixth and seventh conductive tracks, respectively. The second power semiconductor device may comprise a second control electrode configured to switch a power current flowing between the third power electrode and the fourth power electrode. The plurality of electrically conductive layers may further comprise ninth and tenth electrically conductive layers which are spaced apart from one another along the stacking direction. The second control electrode may be electrically connected to the ninth electrically conductive layer, which is further electrically connected to the sixth conductive track; and the third power electrode may be electrically connected to the tenth electrically conductive layer, which is further electrically connected to the seventh conductive track. Alternatively, the second control electrode and the third power electrode may be electrically connected to spaced-apart conductive tracks of the ninth electrically conductive layer respectively. The fourth and fifth electrically conductive layers may be arranged between the third/sixth electrically conductive layer and the ninth electrically conductive layer.

The plurality of electrically conductive layers may further comprise: a first patterned interface layer on a first surface of the circuit board that faces the first power semiconductor device; and a second patterned interface layer on a second surface of the circuit board that faces the second power semiconductor device. The second surface may be opposite to the first surface.

Each of the first and second patterned interface layers may comprise spaced-apart conductive regions which are electrically connected to the conductive tracks of the respective first or second patterned electrically conductive layer.

The circuit board may further comprise at least one through-layer via which electrically connects each conductive region of the patterned interface layers to a respective one of the electrically conductive layers.

The power semiconductor module may further comprise: a first heat removal structure thermally coupled to the first substrate; and/or a second heat removal structure thermally coupled to the second substrate.

The term “thermally coupled” includes that one or more intervening element(s) may exist between the thermally coupled elements.

At least one of the first and second power semiconductor devices may comprise a wide bandgap power semiconductor device.

The circuit board may be a flexible circuit board.

Advantageously, a flexible circuit board is useful for accommodating differences in thickness of components and devices mounted on the substrate.

The plurality of electrically conductive layers may comprise copper. The plurality of electrically insulating layers may comprise polyimide. The plurality of electrically conductive layers and the plurality of electrically insulating layers may be arranged in an alternating manner.

According to a second aspect of this disclosure there is provided a method of operating the power semiconductor module of the first aspect, the method comprising: electrically connecting the first and second conductive tracks to a DC power supply.

The second conductive track may operate with a higher voltage potential than the first conductive track. In other words, the second conductive track may be connected to a DC+ node of the DC power supply, and the first conductive track may be connected to a DC− node of the DC power supply.

The first power semiconductor device may comprise a first control electrode configured to switch a power current flowing between the first power electrode and the second power electrode. The second power semiconductor device may comprise a second control electrode configured to switch a power current flowing between the first power electrode and the second power electrode. The method may further comprise: applying control signals to the first control electrode and the second control electrode so as to generate an AC output at the third conductive track.

According to a third aspect of this disclosure there is provided a method of manufacturing a power semiconductor module, comprising: attaching a first power semiconductor device to a first surface of a circuit board, wherein the first power semiconductor device comprises first and second power electrodes, and wherein the circuit board comprises a plurality of electrically conductive layers stacked with a plurality of electrically insulating layers along a stacking direction, at least one of the electrically insulating layers being arranged between adjacent ones of the electrically conductive layers, and wherein the plurality of electrically conductive layers comprises first, second and third electrically conductive layers which are spaced apart from one another along the stacking direction; attaching a second power semiconductor device to a second surface of the circuit board, wherein the second surface is opposite to the first surface, and the second power semiconductor device comprises third and fourth power electrodes; mounting the first surface of the circuit board to a first substrate such that the first power semiconductor device is between the circuit board and the first substrate; and mounting the second surface of the circuit board to a second substrate such that the second power semiconductor device is between the circuit board and the second substrate; wherein attaching the first power semiconductor device and attaching the second power semiconductor device comprise: electrically connecting the first power electrode to the first electrically conductive layer; electrically connecting each of the second and third power electrodes to the third electrically conductive layer; and electrically connecting the fourth power electrode to the second electrically conductive layer.

The first substrate may comprise a first electrically insulating body and a first patterned electrically conductive layer arranged on a surface of the first electrically insulating body that faces the circuit board. The second substrate may comprise a second electrically insulating body and a second patterned electrically conductive layer arranged on a surface of the second electrically insulating body that faces the circuit board. The first patterned electrically conductive layer may comprise a first conductive track. The second patterned electrically conductive layer may comprise a second conductive track. One of the first and second patterned electrically conductive layers further may comprise a third conductive track. The method may further comprise: mounting first, second and third power terminals directly on the first, second and third conductive tracks, respectively.

Mounting the first surface of the circuit board to the first substrate and mounting the second surface of the circuit board to the second substrate may comprise: electrically connecting the first power terminal to the first electrically conductive layer; electrically connecting the second power terminal to the second electrically conductive layer, and electrically connecting the third power terminal to the third electrically conductive layer.

The term “about” or “approximately” used in the present disclosure indicate a degree of variability (e.g., 20%) in the stated numerical values.

It would also be understood that the terms “first” to “tenth” are simply used in the present disclosure to label the relevant elements (e.g., “power electrode”, “electrically conductive layer” etc.) for the ease of description, and do not imply any limitations to the sequence, locations or total number of the relevant elements.

Where appropriate any of the optional features described above in relation to one of the aspects of the disclosure may be applied to another one of the aspects of the disclosure.

### BRIEF DESCRIPTION OF THE DRAWINGS

In order that the disclosure may be more fully understood, a number of embodiments of the disclosure will now be described, by way of example, with reference to the accompanying drawings, in which:

FIG. 1 schematically illustrates a circuit diagram of a half-bridge circuit structure with parasitic capacitances;

FIG. 2 is a schematic representation of a top plan view of a power semiconductor module according to a first embodiment of the present disclosure;

FIG. 3 a schematic representation of a cross-sectional view of the power semiconductor module of FIG. 2 when the module is cut along line III-III′ in FIG. 2;

FIG. 4 is a schematic representation of a top plan view of a lower substrate used within the power semiconductor module of FIG. 2 with power semiconductor devices mounted thereon;

FIG. 5 is a schematic representation of a bottom plan view of a circuit board used within the power semiconductor module of FIG. 2;

FIG. 6 is a schematic representation of a bottom plan view of an upper substrate used within the power semiconductor module of FIG. 2 with power semiconductor devices mounted thereon;

FIG. 7 is a schematic representation of a top plan view of the circuit board used within the power semiconductor module of FIG. 2;

FIG. 8 schematically illustrates paths of power circuit currents through the power semiconductor module of FIG. 2;

FIG. 9 schematically illustrates paths of gate circuit currents for power semiconductor devices within the power semiconductor module of FIG. 2;

FIG. 10 is a schematic representation of a top plan view of a power semiconductor module according to a second embodiment of the present disclosure;

FIG. 11 is a schematic representation of a top plan view of a power semiconductor module according to a third embodiment of the present disclosure;

FIG. 12 schematically illustrates processing steps of a method for manufacturing a power semiconductor module according to the present disclosure.

In the figures, like parts are denoted by like reference numerals.

It will be appreciated that the drawings are for illustration purposes only and are not drawn to scale.

### DETAILED DESCRIPTION OF THE PREFERRED EMBODIMENTS

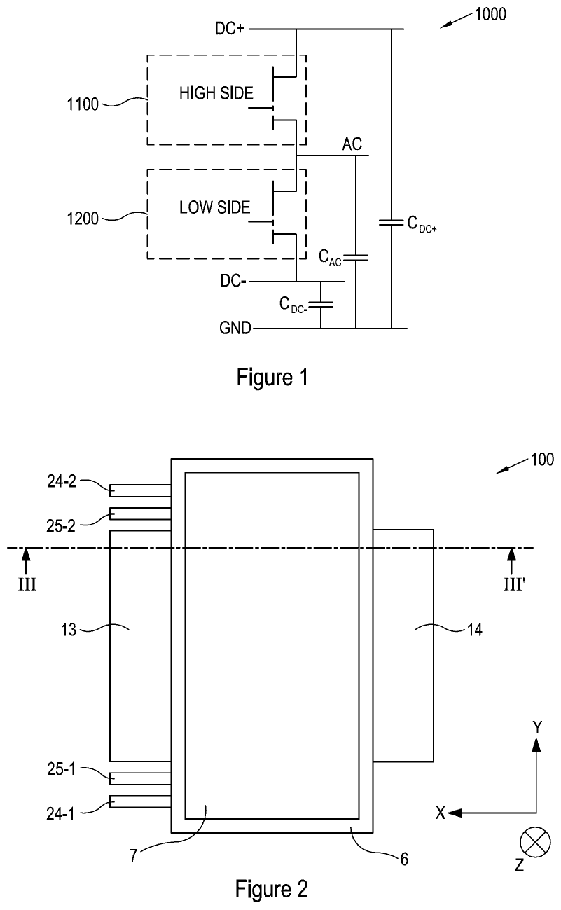

FIGS. 2 to 7 schematically illustrates the structure of a power semiconductor module 100 (hereinafter, “module 100”) that realises the half-bridge circuit 1000 of FIG. 1.

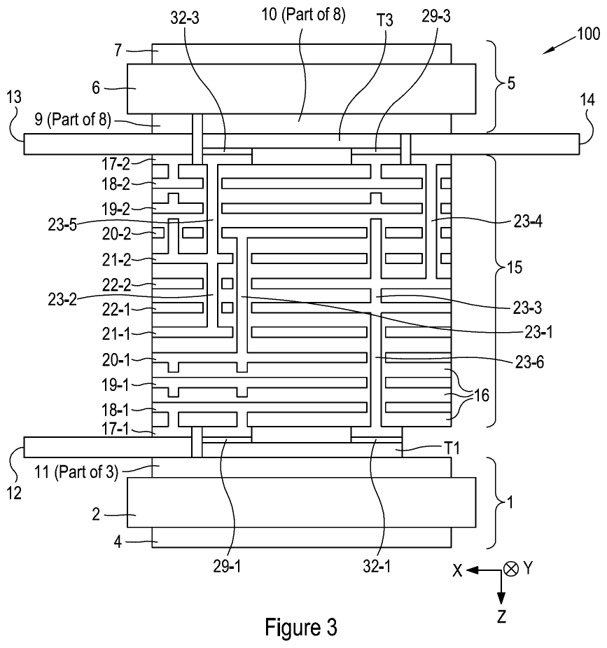

FIG. 2 is a top plan view of the module 100 shown in an X-Y plane when the module 100 is viewed along a vertical Z direction from the top. As shown in FIG. 2, the module 100 includes power terminals 13 and 14 which correspond to the DC+ power terminal and the AC output terminal of the half-bridge circuit 1000, respectively. The module also has a DC− power terminal 12 which is exactly below the DC+ terminal 13 and thus remains invisible in FIG. 2. The module 100 further includes gate control terminals 24-1 and 24-2 (which are collectively referred to as 24), and Kelvin source control terminals 25-1 and 25-2 (which are collectively referred to as 25). The module 100 also has a lower substrate 1, an upper substrate 5 and a circuit board 15 which are described in more detail below with reference to FIGS. 3 to 7.

FIG. 3 is a cross-sectional view of the module 100 along an X-Z plane when the module 100 is cut along a line III-III′ in FIG. 2. As shown in FIG. 3, the lower substrate 1 has an electrically insulating body 2 with a patterned electrically conductive layer 3 arranged at its top surface, and another electrically conductive layer 4 arranged at its bottom surface. The upper substrate 5 has an electrically insulating body 6 with an electrically conductive layer 7 arranged at its top surface and a patterned electrically conductive layer 8 arranged at its bottom surface. The electrically insulating bodies 2, 6 are typically made of ceramic or a suitable polymer. The conductive layers 3, 4, 7, 8 may be made of copper or other suitable conducting material such aluminum, copper-molybdenum alloy, or copper-tungsten alloy etc. The substrates 1, 5 may be direct bonded copper (DBC) substrates, directed bonded aluminium (DBA) substrates or active metal brazed (AMB) substrates. The substrates 1, 5 may be referred to as “first substrate” and “second substrate”, respectively.

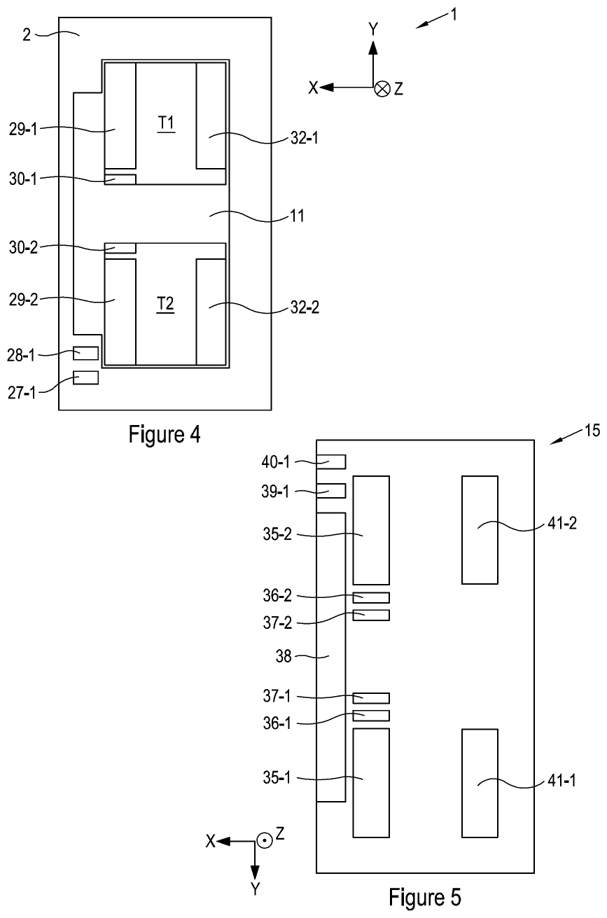

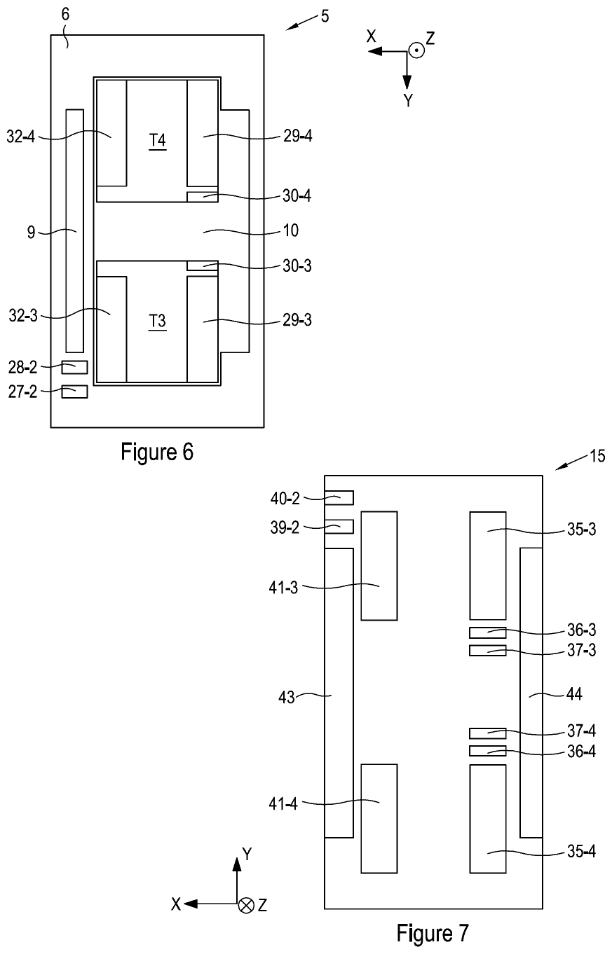

Power semiconductor devices (hereinafter, “devices”) T1 and T2 are mounted on the patterned electrically conductive layer 3 of the lower substrate 1 (FIG. 4). Power semiconductor devices T3 and T4 are mounted on the patterned electrically conductive layer 8 of the upper substrate 5 (FIG. 6). The devices T1 and T2 are electrically connected in parallel with each other and collectively form the low-side power switch 1200. The devices T3 and T4 are electrically connected in parallel and collectively form the high-side power switch 1100. The devices T1-T4 may be pre-packaged bare dies or packaged chips. Only devices T1 and T3 are shown in FIG. 3 corresponding to the location of the cutting line III-III′. A circuit board 15 is located between the devices T1-T2 and the devices T3-T4. Therefore, the lower substrate 1, the devices T1-T2, the circuit board 15, the devices T3-T4, and the upper substrate 5 are stacked along the vertical Z direction.

FIG. 4 shows a top plan view of the lower substrate 1 with the devices T1-T2 mounted thereon. FIG. 7 shows a top plan view of the circuit board 15. The views of FIGS. 4 and 7 are from the same angle as FIG. 2. It would be understood that in FIGS. 4 and 7, the “top surface” of an element refers to the visible surface of the relevant element, and the “bottom surface” is at an opposite side of the element and hence remains invisible.

FIG. 5 shows a bottom plan view of the circuit board 15. FIG. 6 shows a bottom plan view of the upper substrate 5 with the devices T3-T4 mounted thereon. The views of FIGS. 5 and 6 are from an opposite angle as compared to FIG. 2. It would be understood that in FIGS. 5 and 6, the “bottom surface” of an element refers to the visible surface of the relevant element, and the “top surface” is at an opposite side of the element and hence remains invisible.

As shown in FIG. 4, the patterned electrically conductive layer 3 (at the top of the electrically insulating body 2) includes conductive tracks 11, 27-1, 28-1 that are spaced apart from one another (hence electrically insulated from one another if further electrical connections were not provided). The conductive track 11 is directly bonded with (and thus electrically connected to) the DC− power terminal 12, and may also be referred to as a “first conductive track”. The conductive tracks 27-1, 28-1 are directly bonded with the gate control terminal 24-1 and the Kelvin source control terminal 25-1, respectively, and thus are gate and Kelvin source pads. The devices T1 and T2 are mounted on the first conductive track 11 and are spaced apart from one another along the Y direction.

As shown in FIG. 6, the patterned electrically conductive layer 8 (at the bottom of the electrically insulating body 6) includes conductive tracks 9, 10, 27-2, 28-2 that are spaced apart from one another (hence electrically insulated from one another if further electrical connections were not provided). The conductive tracks 9 and 10 are directly bonded with the DC+ and AC power terminals 13, 14, respectively, and may also be referred to as “second conductive track” and “third conductive track”. The conductive tracks 27-2, 28-2 are directly bonded with the gate control terminal 24-2 and the Kelvin source control terminal 25-2, respectively, and thus are gate and Kelvin source pads. The devices T3 and T4 are both mounted on the third conductive track 10 and are spaced apart from one another along the Y direction.

With reference to FIG. 4, the device T1 has a gate electrode 30-1, a source electrode 29-1 and a drain electrode 32-1, all of which are formed at the top surface of the device T1. The gate electrode 30-1 is a control electrode, and the source and drain electrodes 29-1, 32-1 are power electrodes. In particular, a voltage difference between the gate electrode 30-1 and the source electrode 29-1 determines the on/off status of a power current path between the drain electrode 32-1 and the source electrode 29-1. Similarly, the device T2 has a gate electrode 30-2, a source electrode 29-2 and a drain electrode 32-2 at its top surface. The bottom surfaces of the devices T1-T2 are semiconductor substrates of the devices T1-T2 and are directly mounted on the first conductive track 11. Therefore, the devices T1-T2 are thermally coupled to the lower substrate 1. The source electrodes 29-1, 29-2 of the low-side devices T1-T2 may be referred to as “first power electrode”. The drain electrodes 32-1, 32-2 of the low-side devices T1-T2 may be referred to as “second power electrode”.

With reference to FIG. 6, the device T3 has a gate electrode 30-3, a source electrode 29-3 and a drain electrode 32-3, all of which are formed at the bottom surface of the device T3. The device T4 has a gate electrode 30-4, a source electrode 29-4 and a drain electrode 32-4 at its bottom surface. The top surfaces of the devices T3-T4 are semiconductor substrates of the devices T3-T4 and are directly mounted on the third conductive track 10. Therefore, the devices T3-T4 are thermally coupled to the upper substrate 5. The source electrodes 29-3, 29-4 of the high-side devices T3-T4 may be referred to as “third power electrode”. The drain electrodes 32-3, 32-4 of the high-side devices T3-T4 may be referred to as “fourth power electrode”.

The devices T1-T4 are typically uni-directional devices, meaning that the devices block voltage and conduct current in the same direction. For example, the low-side devices T1, T2 block a voltage with a higher potential at the second/drain power electrode than at the first/source power electrode, and the high-side devices T3, T4 block a voltage with a higher potential at the fourth/drain power electrode than at the third/source power electrode.

While it is not shown in any of the figures, it would be understood that bonding materials (e.g., solder or sintering paste, or conductive epoxy resin) would be used as interface materials to securely bond the devices T1 to T4 (and the terminals 12-14 and 24-25) to the respective conductive tracks.

In this example, the devices T1-T4 are GaN HEMTs. However, it would be appreciated that the devices T1-T4 may be other types of WBG power transistors, or may be based upon non-WBG semiconductor materials (e.g., Silicon, or Silicon carbide). For example, the devices T1-T4 may comprise one or more of insulated gate bipolar transistors (IGBT), power metal-oxide-semiconductor field-effect transistors (MOSFET), injection enhanced gate transistors (IEGT), power bipolar junction transistors (BJT), integrated gate-commutated thyristors (IGCT), and gate turn-off thyristors (GTO), etc. In the event that devices T1-T4 are IGBT-based, the Kelvin source control terminals 25 may be referred to as auxiliary emitter terminals. Further, one or more of devices T1-T4 may further include a power diode (such as a fast recovery diode or a Schottky diode) in anti-parallel connections with the power transistor therein. Further still, it would be understood that the number of power semiconductor devices included within each of the high-side and low-side power switches 1100, 1200 can be suitably varied depending upon the required rating of the half-bridge circuit 1000.

The circuit board 15 is used to realise the electrical connections between the electrodes 29, 30, 32 of the devices T1-T4 and the terminals 12-14 and 24-25 of the module 100.

A cross-sectional view of the circuit board 15 is shown in FIG. 3. With reference to FIG. 3, the circuit board 15 includes a lower patterned electrically conductive interface layer 17-1 (hereinafter, “interface layer”) at its bottom surface for direct bonding with the electrodes of the devices T1-T2 and the terminals 12, 24-1, 25-1 of the module 100. The circuit board 15 also has an upper patterned electrically conductive interface layer 17-2 at its top surface for direct bonding with the electrodes of the devices T3-T4 and the terminals 13, 14, 24-2, 25-2 of the module 100.

The circuit board 15 further includes multiple electrically conductive layers 18-1 to 22-1 and 22-2 to 18-2 arranged between the interface layers 17-1, 17-2 along the Z-direction. The circuit board 15 also has electrically insulating layers 16 stacked with the conductive layers in an alternating manner along a stacking direction (e.g., the Z or Z-direction). While FIG. 3 shows that a single electrically insulating layer 16 is arranged between adjacent conductive layers, it would be appreciated that more than one electrically insulating layer may be used between some of the adjacent conductive layers. The conductive layers 20-1, 21-1, 22-1 may be referred to as “first electrically conductive layer” to “third electrically conductive layer”, respectively. The conductive layers 20-2, 21-2, 22-2 may be referred to as “fourth electrically conductive layer” to “sixth electrically conductive layer”, respectively. The conductive layers 19-1, 18-1 may be referred to as “seventh conductive layer” and “eighth conductive layer”, respectively. The conductive layers 19-2, 18-2 may be referred to as “ninth conductive layer” and “tenth conductive layer”, respectively.

Due to the existence of the electrically insulating layers 16, adjacent conductive layers would not be electrically shorted to one another without the use of conductive through-layer vias. As shown in FIG. 3, the conductive layers 20-1 and 20-2 (collectively referred to as 20) are electrically connected to one another by a through-layer via 23-1. Therefore, the conductive layers 20 share a common voltage potential during operation of the module 100. Similarly, the conductive layers 21-1 and 21-2 (collectively referred to as 21) are electrically connected to one another by a through-layer via 23-2. Therefore, the conductive layers 21 share a common potential in use. The conductive layers 22-1 and 22-2 (collectively referred to as 22) are electrically connected to one another by a through-layer via 23-3. Therefore, the conductive layers 22 share a common potential in use.

In FIG. 3, the through-layer vias 23 are shown in defined locations for ease of understanding. It would be understood that in reality, the through-layer vias 23 are distributed across the whole X-Y plane of the circuit board 15, so as to minimise resistance and inductance between interconnected layers. The through-layer vias of the circuit board 15 generally extend along the vertical stacking direction (e.g., the Z or Z-direction), but it would be understood that the vias may alternatively form a small angle with respect to the stacking direction.

The multi-layer circuit board 15 may be manufactured by common processes. A flexible circuit board 15 is preferred to accommodate differences in thicknesses of the devices T1-T2 and the terminals 12, 24-1, 25-1, and to accommodate differences in thicknesses of the devices T3-T4 and the terminals 13, 14, 24-2, 25-2. In this way, the circuit board 15 can be easily bonded to all of the devices T1-T4 and the terminals 12-14, and 24-25. The electrically conductive layers 17-22 may be made of copper, and the electrically insulating layers 16 may be made of high temperature insulating material, such as polyimide. Typical layer thicknesses are 70 μm for each of the electrically conductive layers and 12 μm for each of the electrically insulating layers, although other thicknesses are possible. In general, thick conductor and thin insulator layers are preferred. This is described below in more detail. With the typical layer thicknesses described above, the total thickness of the circuit board 15 along the stacking direction is generally within about 1 millimeter (mm). In the meantime, the size of the circuit board 15 may be around 20-30mm along the X axis, and 50-60 mm along the Y axis. Therefore, the thickness of the circuit board 15 is merely a small percentage (e.g., less than 5%) of its size along the X or Y axis. This allows the circuit board 15 to be easily deformable, thereby enhancing the flexibility of the circuit board 15. The circuit board 15 may also be referred to as a foil composite or a laminate structure.

FIG. 5 shows the layout of the lower interface layer 17-1, and FIG. 7 shows the layout of the upper interface layer 17-2. Each of the interface layers 17-1, 17-2 is a patterned layer including a plurality of conductive regions that are spaced apart from one another (hence electrically insulated from one another if further electrical connections were not provided). The interface layers 17-1, 17-2 may be formed by selectively etching a continuous electrically conductive layer.

With reference to FIG. 5, the lower interface layer 17-1 provides source contact regions 35-1, 35-2 for electrical connection with the source electrodes 29-1, 29-2 of the devices T1-T2, respectively, drain contact regions 41-1, 41-2 for electrical connection with the drain electrodes 32-1, 32-2 of the devices T1-T2, gate contact regions 37-1, 37-2 for electrical connection with the gate electrodes 30-1, 30-2 of the devices T1-T2, and Kelvin source contact regions 36-1, 36-2 for electrical connection with the source electrodes 29-1, 29-2 of the devices T1-T2. The lower interface layer 17-1 further provides a power contact region 38 for electrical connection with the DC− terminal 12 (hence the conductive track 11 of the lower substrate 1), and control-signal contact regions 39-1, 40-1 for electrical connection with the control terminals 25-1, 24-1 of the module 100 respectively (hence the conductive tracks 28-1, 27-1 as shown in FIG. 4). When the circuit board 15 is mounted on top of the devices T1-T2 and the lower substrate 1, the conductive regions of the lower interface layer 17-1 are directly mounted on the corresponding electrodes of the devices T1-T2 and the corresponding terminals of the module 100 as described above.

With reference to FIG. 7, the upper interface layer 17-2 provides source contact regions 35-3, 35-4 for electrical connection with the source electrodes 29-3, 29-4 of the devices T3-T4, respectively, drain contact regions 41-3, 41-4 for electrical connection with the drain electrodes 32-3, 32-4 of the devices T3-T4, gate contact regions 37-3, 37-4 for electrical connection with the gate electrodes 30-3, 30-4 of the devices T3-T4, and Kelvin source contact regions 36-3, 36-4 for electrical connection with the source electrodes 29-3, 29-4 of the devices T3-T4. The upper interface layer 17-2 further provides power contact regions 43, 44 for electrical connection with the DC+ terminal 13 and the AC terminal 14 (hence the conductive tracks 9 and 10 of the upper substrate 5), and control-signal contact regions 39-2, 40-2 for electrical connection with the control terminals 25-2, 24-2 of the module 100 respectively (hence the conductive tracks 28-2, 27-2 as shown in FIG. 6). When the circuit board 15 is mounted to the devices T3-T4 and the upper substrate 5, the conductive regions of the upper interface layer 17-2 are directly mounted on the corresponding electrodes of the devices T3-T4 and the corresponding terminals of the module 100 as described above.

The circuit board 15 further includes through-layer vias which electrically connect the conductive regions of the interface layers 17 to corresponding one(s) of the electrically conductive layers 18 to 22 within the circuit board 15.

In particular, the contact regions 41-3, 41-4 (FIG. 7) are electrically connected to the conductive layers 21 by through-layer vias (e.g., 23-5 in FIG. 3). The conductive layers 21 are electrically connected to the power contact region 43 (FIG. 7) by further through-layer vias (not shown in FIG. 3). Therefore, the drain electrodes 32-3, 32-4 of the high-side devices T3, T4 are electrically connected to the conductive layers 21, which are electrically connected to the DC+ power terminal 13.

The contact regions 35-3, 35-4 (FIG. 7) are electrically connected to the conductive layers 22 by through-layer vias (not shown in FIG. 3). The contact regions 41-1, 41-2 (FIG. 5) are electrically connected to the conductive layers 22 by through-layer vias (e.g., 23-6 in FIG. 3). The conductive layers 22 are electrically connected to the power contact region 44 (FIG. 7) by further through-layer vias (e.g., 23-4 in FIG. 3). Therefore, the source electrodes 29-3, 29-4 of the high-side devices T3, T4 and the drain electrodes 32-1, 32-2 of the low-side devices T1, T2 are electrically connected to the conductive layers 22, which are further electrically connected to the AC output power terminal 12.

The contact regions 35-1 and 35-2 (FIG. 5) are electrically connected to the conductive layers 20 by through-layer vias (not shown in FIG. 3). The conductive layers 20 are electrically connected to the power contact region 38 (FIG. 5) by further through-layer vias (not shown in FIG. 3). Therefore, the source electrodes 28-1, 28-2 of the low-side devices T1, T2 are electrically connected to the conductive layers 17, which are electrically connected to the DC− power terminal 12.

Accordingly, the conductive layers 20, 21, 22 may also be referred to DC−, DC+ and AC conductive layers, respectively, because they share the voltage potentials of the DC− power terminal 12, the DC+ power terminal 13, and the AC output power terminal 14.

Further, the gate contact regions 37-3, 37-4 are electrically connected to the conductive layer 19-2 by through-layer vias (not shown in FIG. 3). The conductive layer 19-2 is further electrically connected to the control-signal contact region 40-2 by further through-layer vias (not shown in FIG. 3). Therefore, the gate electrodes 30-3, 30-4 of the high-side devices T3 and T4 are electrically connected to the conductive layer 19-2, which is electrically connected to the gate control terminal 24-2. The Kelvin source contact regions 36-3, 36-4 are electrically connected to the conductive layer 18-2 by through-layer vias (not shown in FIG. 3). The conductive layer 18-2 is further electrically connected to the control-signal contact region 39-2 by further through-layer vias (not shown in FIG. 3). Therefore, the source electrodes 29-3, 29-4 of the high-side devices T3 and T4 are electrically connected to the conductive layer 18-2, which is electrically connected to the Kelvin source control terminal 25-2. Accordingly, the conductive layers 19-2, 18-2 of the circuit board 15 may also be referred to as gate and Kelvin source control layers of the high-side devices T3, T4, because they share the voltage potentials of the control terminals 24-2, 25-2.

Similarly, the gate electrodes 30-1, 30-2 of the low-side devices T1 and T2 are electrically connected to the conductive layer 19-1, which is electrically connected to the gate control terminal 24-1, and the source electrodes 29-1, 29-2 of the low-side devices T1 and T2 are electrically connected to the conductive layer 18-1, which is electrically connected to the Kelvin source control terminal 25-1. Accordingly, the conductive layers 19-1, 18-1 of the circuit board 15 may also be referred to as gate and Kelvin source control layers of the low-side devices T1, T2, because they share the voltage potentials of the control terminals 24-1, 25-1.

In use of the module 100, a DC power supply is connected between the DC+ power terminal 13 and the DC− power terminal 12, and control signals are applied to the gate control terminals 24 and the Kelvin source control terminals 25 to control the on/off statuses of the high-side devices T3, T4 and the low-side devices T1, T2, thereby controlling the voltage/current output by the AC power terminal 14. The module 100 typically provides one phase of a power converter at the AC power terminal 14. The use of the Kelvin source control terminals 25 reduces the power and control loop common inductance of the devices T1-T2, and of the devices T3-T4. Reducing the power and control loop common inductance is useful for improving the simultaneous switching of the devices T1-T2 (or the devices T3-T4), thereby improving the current sharing between the devices T1-T2 (or the devices T3-T4) and thus the reliability of the module 100 as a whole.

With reference to FIG. 3, the conductive layers of the circuit board 15 are arranged in such an order as to shield sensitive elements (e.g., the gate circuitry, and the DC− conductive layers 20) of the module 100 against EMI. The EMI is primarily caused by the current and voltage transients in the AC conductive layers 22. Therefore, the objective is to shield the sensitive elements from the AC conductive layers 22. In the example of FIG. 3, the pair of AC conductive layers 22 are first sandwiched between the pair of DC+ conductive layers 21. The pair of DC− conductive layers 20 then sandwich the DC+ conductive layers 21 and the AC conductive layers 22. Generally speaking, the voltage potential of the DC+ conductive layers 21 (which is equal to the potential of the DC+ power terminal 13) is nominally fixed by an external circuitry and is not a reference voltage for the gate circuitry of either high-side or low-side devices. Therefore, the DC+ conductive layers 21 shield the DC− conductive layers 20 from emissions of the AC conductive layers 22. The DC− conductive layers 20 are sensitive elements, because in some applications such as electric vehicles, noises on the DC− conductive layers 20 may affect other systems of the same vehicle via a shared ground terminal GND. The gate circuit layers 18, 19 are then positioned outside the DC−−DC+−AC−AC−DC+−DC− sandwich. In this way, the gate circuit layers 18, 19 are also shielded from EMI caused by the AC conductive layers 22.

Further, in the example of the module 100, since the AC conductive layers 22 are sandwiched by the DC+ conductive layers 21 and the DC− conductive layers 20, the environment outside the module 100 (where other sensitive circuitry may be located) is also shielded from EMI caused by the AC conductive layers 22.

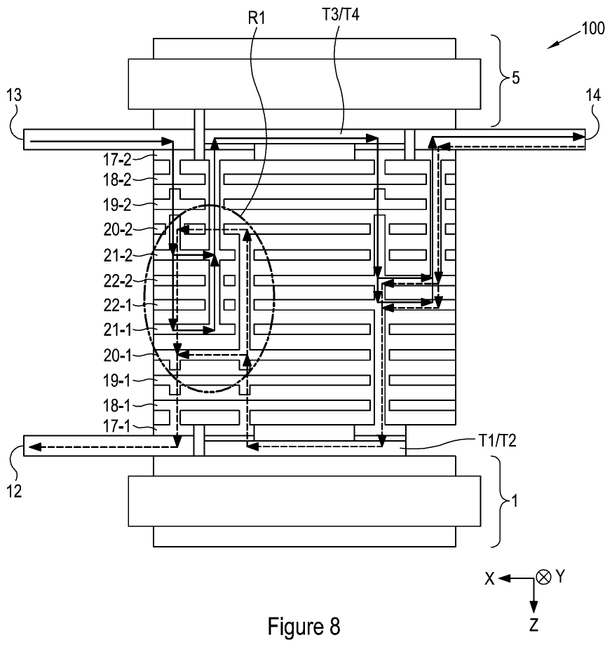

FIG. 8 schematically illustrates power circuit current paths during operation of the module 100. In accordance with the electrical connections described above, it would be understood that power currents flow through multiple conductive layers of the circuit board 15 joined by vertical through-layer vias within the circuit board 15. Because the through-layer vias are not constrained within a single cross section (along the X-Z plane) of the module 100, the current paths are in fact three-dimensional. FIG. 6 is obtained by projecting the three-dimensional current paths of power circuit to a single two-dimensional X-Z plane. Therefore, overlapped vertical current paths as shown in FIG. 6 may not flow in the same physical conductors. However, overlapped horizontal current paths shown in FIG. 6 flow in the same conductive layer of the circuit board 15.

In FIG. 8, the solid lines show the power current flowing from the DC+ power terminal 13 to the AC output terminal 14. After entering the circuit board 15 (at the power contact region 43 of the upper interface layer 17-2), the power current flows downwards to the DC+ conductive layers 21, then laterally along the DC+ conductive layers 21, before flowing upwards to the drain electrodes 32-3, 32-4 of the high-side devices T3, T4. The power current further flows laterally from the drain electrodes 32-3, 32-4 to the source electrodes 29-3, 29-4 of the high-side devices T3, T4, then downwards to the AC conductive layers 22, before following upwards to the AC output terminal 14.

The dashed lines in FIG. 8 shows the power current flowing from the AC output terminal 14 to the DC− power terminal 12. After entering the circuit board 15 (at the power contact region 44 of the upper interface layer 17-2), the power current flows downwards to the AC conductive layers 22, then laterally along the AC conductive layers 22, before flowing downwards to the drain electrodes 32-1, 32-2 of the low-side devices T1, T2. The power current further flows laterally from the drain electrodes 32-1, 32-2 to the source electrodes 29-1, 29-2 of the low-side devices T1, T2, then upwards to the DC− conductive layers 20, before following downwards to the DC− power terminal 12.

As shown in FIG. 8, power circuit current paths are contained primarily within the electrically conductive layers of the circuit board 15. Considering that the total thickness of the circuit board 15 along the Z direction is within about 1 mm, physical sizes of power current loops are significantly reduced as compared to traditional module designs using wire bonds. Further, because the low-side and high-side devices are located at opposite sides of the circuit board 15, the lateral dimension of the power current loops along the X direction is approximately half of the size of traditional module designs wherein all devices are typically mounted on the same side of one substrate. Since current loops cause radiated EMI, reducing the sizes of power current loops is useful for minimising EMI.

With reference to FIG. 8, it can be seen that the current path from DC+ to AC and the current path from AC to DC− are in close proximity. In particular, in a region R1 as shown in FIG. 8, the two current paths have opposite flow directions, and the distance between the two current paths along the Z direction is merely the thickness of a single electrically insulating layer (in the order of tens of um). This arrangement promotes flux cancellation of the opposite current flows and accordingly causes a reduction of parasitic inductances in the interconnections between DC+/DC− and AC. In addition, the multi-layer nature of the circuit board 15 allows power circuit current to be carried in more than one conductive layer of the circuit board 15. In the example of the module 100, a pair of conductive layers (e.g., layers 20-1&20-2, 21-1&21-2 and 22-1&22-2) are used to share the power circuit current at any point of the current paths. This arrangement effectively increases the cross-section area (along the Y-Z plane) of the power conductors, thereby reducing the overall electrical resistance and inductance in the interconnections between DC+/DC− and AC. Reducing the parasitic inductances in the interconnections between DC+/DC− and AC is useful for both minimising EMI and reducing the magnitude of voltage overshoot above the DC supply voltage of the module 100.

It would be understood that reducing the thickness of the electrically insulating layer between opposite current flows is useful for promoting flux cancellation of the opposite current flows, thereby causing a further reduction of parasitic inductances in the interconnections between DC+/DC− and AC. It would also be appreciated that increasing the thickness of electrically conductive layers is useful for reducing the overall electrical resistance and inductance in the interconnections between DC+/DC− and AC. Therefore, in general, thick electrically conductive layers and thin electrically insulating layers are preferred. A thickness of each electrically conductive layer may be in a range of between 50 μm and 140 μm, and a thickness of each electrically insulating layer may be in a range of between 10 μm and 30 μm, depending upon particular performance requirements.

Further with reference to FIG. 8, due to the fact that the high-side devices T3, T4 and the low-side devices T1, T2 are stacked at opposite sides of the circuit board 15, the conduction path between DC+ and AC power terminals 13, 14, and the conduction path between DC− and AC power terminals 12, 14 are generally symmetric and have similar lengths within the circuit board 15 along the X-Z plane. This means that the parasitic inductances in the interconnections between DC+/DC− and AC power terminals are generally balanced. This is also useful for reducing electromagnetic emissions of the module 100 because imbalanced inductances cause differential currents and thus EMI.

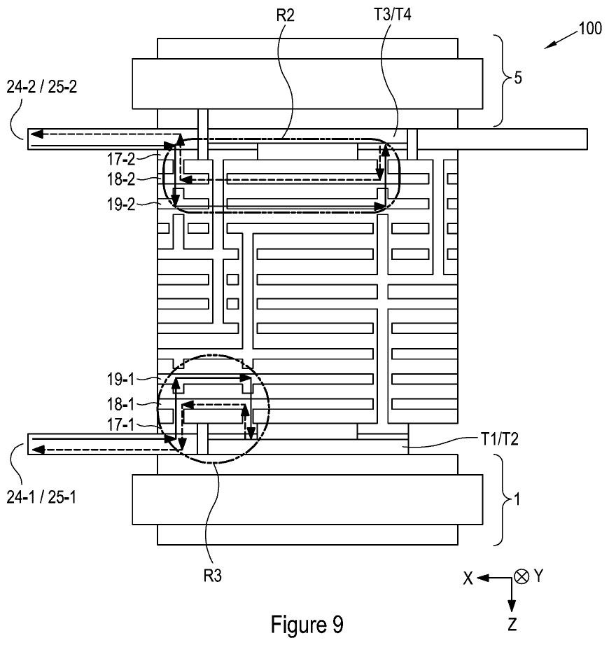

FIG. 9 schematically illustrates gate circuit current paths of the low-side devices T1, T2, and of the high-side devices T3-T4. Similar to FIG. 8, FIG. 9 is obtained by projecting real three-dimensional current paths to a single two-dimensional X-Z plane. Therefore, overlapped vertical current paths as shown in FIG. 9 in fact may not flow in the same physical conductors. However, overlapped horizontal current paths shown in FIG. 9 flow in the same conductive layer of the circuit board 15.

In FIG. 9, the solid lines show the current flowing from the respective gate control terminal 24 of the module 100, via the corresponding gate control layer 19, to the gate electrodes 30 of the devices. The dashed lines show the current flowing from the source electrodes 29 of the devices, via the corresponding Kelvin source control layer 18, to the respective Kelvin source control terminal 25 of the module 100.

With reference to FIG. 9, it can be seen that, in regions R2 and R3, the gate circuit currents flow in opposite directions in the Gate control layer 19 and the corresponding Kelvin source control layer 18, which are separated by a single electrical insulating layer. This arrangement allows the opposite current flows of the gate circuit to be closely coupled, thereby promoting flux cancellation and causing a reduction of parasitic inductances of electrical connections between the gate control terminal 24 and the gate electrode 30, and between the Kelvin source control terminal 25 and the source electrode 29. The reduced parasitic inductances improve the switching speed of the devices T1-T4, and also reduce the risks of falsely triggering the devices T1-T4.

The use of the multi-layer circuit board 15 further allows parasitic capacitances between DC+, DC− and AC potentials to be tailored by varying the area of mutual overlap. For example, in the circuit board 15, the DC+ conductive layers 21 and the DC− conductive layers 20 are separated by a single electrically insulating layer. This arrangement is useful for maximising the parasitic capacitance between the DC+ conductive layers 21 and the DC− conductive layers 20, and thus useful for reducing line voltage ripples caused by high-speed current transients produced by operation of the module 100.

In the example of the module 100, the DC+ and AC power terminals 13, 14 are mounted directly on the patterned electrically conductive layer 8 of the upper substrate 5, and the DC− power terminal 12 is mounted directly on the patterned electrically conductive layer 3 of the lower substrate 1. This direct mounting arrangement improves cooling of the power terminals 12 to 14, because heat generated on/around the power terminals can efficiently dissipate to exterior through the substrates 1, 5 and heat sinks attached to the electrically conductive layers 4, 7 of the substrates 1, 5. Therefore, during operation of the module 100, joints between the power terminals 12 to 14 and its surroundings (e.g., the substrates 1, 5 or dielectric encapsulation of the module 100) would not experience a significant temperature rise. Accordingly, reliability of the joints is improved, and the power cycling capability and the thermal reliability of the module 100 are also improved. The direct mounting arrangement of the power terminals 12 to 14 is particularly meaningful for modules using WBG power semiconductor devices, since those devices have higher current densities and therefore higher heat flux densities than traditional silicon chips.

In addition, directly mounting the power terminals on the substrates necessitates the provision of conductive tracks 9 to 11 (which act as bonding pads) on the substrates 1, 5. As described above, the conductive track 11 (FIG. 4) is at DC− potential, and the conductive track 9 (FIG. 6) is at DC+ potential. The pad areas of the conductive tracks 9, 11 along the X-Y plane can be easily tailored in order to balance parasitic capacitances from DC+ to GND and DC− to GND. Balanced capacitances from DC+/DC− to ground minimise differential currents which are a cause of EMI. The parasitic capacitances may be balanced by making the conductive tracks 9, 11 occupy approximately the same areas on the electrically insulating body 2 or 6. For example, the conductive track 9 may be modified to have a loop shape surrounding the conductive track 10. Alternatively, the area of the conductive track 9 may be expanded such that the high-side devices T3, T4 are mounted on the conductive track 9 instead of the conductive track 10.

As described above, traditional power semiconductor modules use a combination of wire bonds and patterned copper tracks on an electrically insulating body to realise electrical connections between power semiconductor chips and power terminals. The traditional power semiconductor modules therefore have planar circuit layouts, which have large footprints and high, typically unbalanced parasitics, and significantly limit product performance. In contrast, the module 100 of the present disclosure uses a double-sided circuit board 15 to realise the electrical connections between power semiconductor chips and power terminals, and adopts a stacked structure with the high-side devices placed over the low-side devices. The stacked structure produces a folded current loop, thereby shorting the lengths of power current paths and reducing parasitic inductances, and also permits double-side cooling. The module 100 provides improved design flexibility for more compact module footprints and optimised parasitics, which allows full exploitation of fast-switching capabilities and high current densities of WBG power semiconductor devices (e.g., GaN HEMTs) within the module.

Within the module 100, each of the power semiconductor devices T1-T4 is a lateral power device, meaning that its power electrodes are formed on the same side (e.g., the top surface) of the device and that a power current flows laterally between the power electrodes as shown in FIGS. 3, 4, 6 and 8. The use of lateral devices is particularly advantageous because, with reference to FIG. 8, the power current loops are contained within the circuit board 15 and the conductive regions (close to the top surface) of the lateral devices T1-T4. As compared to the use of vertical devices (where power electrodes are arranged on opposite surfaces of the device), using lateral devices is beneficial for improving the effectiveness of magnetic flux cancellation because the distance between conductors of opposing current flow directions can be kept at a relatively short level and is not opened up by the thickness of the vertical devices. However, it would be appreciated that the module 100 may be modified to use vertical power devices, while still achieving most of the improvements as described above over conventional power modules.

While it is not shown in any of FIGS. 2 to 9, it would further be understood that the module 100 typically includes an encapsulant which fills the space between the circuit board 100 and each of the substrates 1, 5 and also seals the devices T1-T4. The encapsulant is useful for protecting the devices T1-T4 and its associated joints from humidity and corrosive gases. The encapsulant may be made of epoxy moulding compound (EMC), and may be applied by a transfer moulding process. Outer ends of the power terminals 12-14 and the control terminals 24-25 of the module 100 would protrude over the encapsulant and be exposed to an exterior of the module 100. In addition, the bottom electrically conductive layer 4 of the lower substrate 1 and the upper electrically conductive layer 7 of the upper substrate 5 would be substantially exposed to the exterior of the module 100.

In use, a pair of heat removal structures (e.g., heat sinks) may be bonded to the bottom surface of the electrically conductive layer 4 and the top surface of the electrically conductive layer 7 via thermal interface materials (e.g., aluminium nitride), so as to dissipate heat generated by the devices T1-T4 from both sides of the module 100. Alternatively, the electrically conductive layers 4, 7 of the substrates 1, 5 may be omitted such that the heat removal structures are directly mounted to the electrically insulating bodies 2, 6. In this way, the module 100 becomes a double-side cooled module.

It would further be appreciated that the module 100 may comprise different types/numbers of power semiconductor devices that are suitably interconnected to form a different circuit structure (e.g., multiple half-bridge structures, at least one phase of a three-level neutral point clamped inverter, etc.). In particular, this may be achieved by suitably modifying the number of conductive layers included within the circuit board 15, and/or the through-layer connections within the circuit board 15.

Within the module 100, the AC power terminal 14 is mounted between the circuit board 15 and the upper substrate 5. It would be appreciated that the module 100 may be modified such that the AC power terminal 14 is mounted between the circuit board 15 and the lower substrate 1. This may be achieved by adding a conductive track on the patterned electrically conductive layer 3 of the lower substrate 1, adding a corresponding conductive region on the lower interface layer 17-1 of the circuit board, and adding through-layer vias in the circuit board 15 to connect the newly-added conductive region to the AC conductive layers 22.

In the module 100, the gate and Kelvin source control layers 18, 19 have a planar design and each occupy substantially the entire area of the circuit board along the X-Y plane. It would be appreciated that the gate and Kelvin source control layers 18, 19 may be patterned, so as to reduce the parasitic capacitance therebetween. The parasitic capacitance between the control layers 18-1, 19-1 (or between control layers 18-2, 19-2) adds to the input capacitance of the low-side devices T1, T2 (or the high-side devices T3, T4), and reduces the switching speed of the module 100. Therefore, patterning the gate and Kelvin source control layers 18, 19 is useful for improving the switching speed of the module 100.

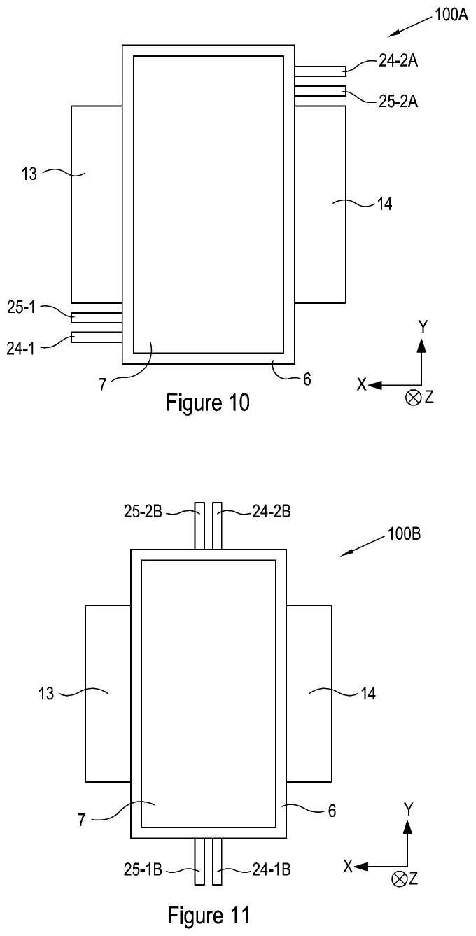

FIGS. 10 and 11 schematically illustrate power semiconductor modules 100A, 100B according to second and third embodiments of the present disclosure. Elements of the modules 100A, 100B that are identical to those of the module 100 are identified using the same labels. Elements of the modules 100A, 100B that correspond to, but are different from those of the module 100 are labelled using the same numerals but with a letter ‘A’ or ‘B’ for differentiation. The features and advantages described above with reference to the first embodiment are generally applicable to the second and third embodiments.

The modules 100A and 100B differ from the module 100 in the positions of the control terminals 24A, 25A, 24B, 25B. This may be achieved by suitably modifying the positions of the conductive tracks 27, 28 (FIGS. 4 and 6) in the patterned electrically conductive layers 3 and 8 of the substrates 1, 5, the positions of the conductive regions 39, 40 (FIGS. 5 and 7) in the two patterned interface layers 17 of the circuit board 15, as well as the positions of the corresponding through-layer vias within the circuit board 15.

It would be appreciated that conductive layers may be omitted from or added to the circuit board 15 in any suitable manner depending upon performance requirements of the module. For example, the AC conductive layers 22-1, 22-2 may be replaced by a single, thicker, conductive layer, and/or more than two interconnected conductive layers may be provided for each of the AC/DC+/DC− conductive layers. Further, the number of conductive layers in the circuit board 15 may be reduced by patterning at least one conductive layer (rather than using a plane-like layer that covers the entire footprint of the circuit board 15). For example, the gate control layer 19-1 and the Kelvin source control layer 18-1 may be replaced by a single patterned conductive layer having two or more conductive tracks which are spaced apart (hence electrically insulated) from one another, with one of the conductive tracks electrically connecting the gate electrodes 30-1, 30-2 of the low-side devices T1, T2 to the gate control terminal 24-1 while another one of the conductive tracks electrically connects the source electrodes 29-1, 29-2 of the low-side devices T1, T2 to the Kelvin source control terminal 25-1. Similarly, the gate control layer 19-2 and the Kelvin source control layer 18-2 may be replaced by a single patterned conductive layer.

It would also be appreciated that the layout of the patterned electrically conductive layers 3, 8, the layout of the interface layers 17, and the layout of the devices T1-T4 may be suitably varied to differ from FIGS. 4 to 7.

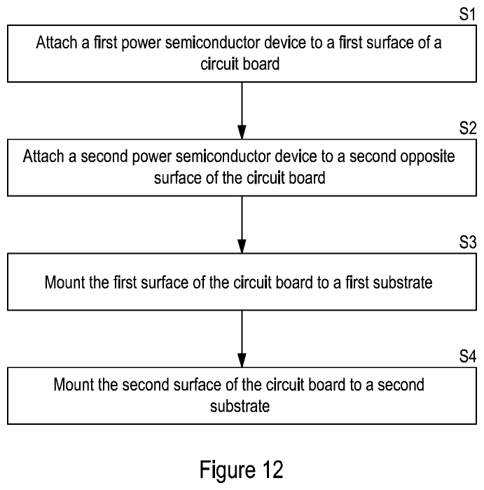

FIG. 12 schematically illustrates processing steps of a method for manufacturing a power semiconductor module (e.g., either of the modules 100, 100A, 100B).

At step S1, a first power semiconductor device (e.g., the low-side devices T1-T2) is attached to a first surface of a circuit board (e.g., the bottom surface of the circuit board 15). The first power semiconductor device comprises first and second power electrodes (e.g., source electrodes 29-1, 29-2, and drain electrodes 32-1, 32-2). The circuit board comprises a plurality of electrically conductive layers stacked with a plurality of electrically insulating layers along a stacking direction (e.g., the direction Z), with at least one of the electrically insulating layers between adjacent ones of the electrically conductive layers. The plurality of electrically conductive layers comprises first, second and third electrically conductive layers (e.g., the layers 20-1, 21-1, 22-1) which are spaced apart from one another along the stacking direction.

At step S2, a second power semiconductor device (e.g., the high-side device T3-T4) is attached to a second surface of a circuit board (e.g., the top surface of the circuit board 15). The second surface is opposite to the first surface. The second power semiconductor device comprises third and fourth power electrodes (e.g., source electrodes 29-3, 29-4, and drain electrodes 32-3, 32-4).

Attaching first and second power semiconductor devices to the circuit board achieves simultaneously (i) an electrical connection between the first power electrode (e.g., the source electrodes 29-1, 29-2) and the first electrically conductive layer (e.g., the layer 20-1); (ii) an electrical connection between each of the second and third power electrodes (e.g., drain electrodes 32-1, 32-2 and source electrodes 29-3, 29-4) and the third electrically conductive layer (e.g., the layer 22-1); and (iii) an electrical connection between the fourth power electrode (e.g., drain electrodes 32-3, 32-4) and the second electrically conductive layer (e.g., the layer 21-1).

The first and second power semiconductor devices may be attached to the circuit board (e.g., the interface layers 17 at opposite sides of the circuit board 15) by a flip-chip process.

At step S3, the first surface of the circuit board is mounted to a first substrate (e.g., the lower substrate 1) such that the first power semiconductor device (e.g., the low-side devices T1-T2) is between the circuit board and the first substrate.

At step S4, the second surface of the circuit board is mounted to a second substrate (e.g., the upper substrate 5) such that the second power semiconductor device (e.g., the high-side device T3-T4) is between the circuit board and the second substrate.

The first substrate may comprise a first electrically insulating body (e.g., the body 2) and a first patterned electrically conductive layer (e.g., the layer 3) arranged on a surface of the first electrically insulating body that faces the circuit board. The second substrate may comprise a second electrically insulating body (e.g., the body 6) and a second patterned electrically conductive layer (e.g., the layer 8) arranged on a surface of the second electrically insulating body that faces the circuit board. The first patterned electrically conductive layer may comprise a first conductive track (e.g., the conductive track 11 of FIG. 4) electrically connected to the first electrically conductive layer. The second patterned electrically conductive layer may comprise a second conductive track (e.g., the conductive track 9 of FIG. 6) electrically connected to the second electrically conductive layer. One of the first and second patterned electrically conductive layers may further comprise a third conductive track (e.g., the conductive track 10 of FIG. 6) electrically connected to the third electrically conductive layer.

Between steps S1&S2 and S3&S4, there may be an optional step of mounting first, second and third power terminals (e.g., the DC− power terminal 12, the DC+ power terminal 13 and the AC output terminal 14) directly on the first, second and third conductive tracks of the substrate, respectively.

Steps S3 and S4 may achieve simultaneously (i) an electrical connection between the first power terminal (e.g., the DC− power terminal 12) to the first electrically conductive layer (e.g., the layer 20-1); (ii) an electrical connection between the second power terminal (e.g., the DC+ power terminal 13) and the second electrically conductive layer (e.g., the layer 21-1); and (iii) an electrical connection between the third power terminal (e.g., the AC output terminal 14) to the third electrically conductive layer (e.g., the layer 22-1).

All joints are made by a suitable technology, which may include sintering, soldering or bonding by conductive epoxy resin.

The method may further include an optional processing step of encapsulating the first and second power semiconductor devices, a space between the circuit board and the first substrate, and a space between the circuit board and the second substrate.

It would be appreciated that the steps may be performed in a temporal order that is different from the order of description. For example, steps S1 and S2 may be performed simultaneously or step S2 may be performed before step S1. Similarly, steps S3 and S4 may be performed simultaneously or step S4 may be performed before step S3.

The terms “having”, “containing”, “including”, “comprising” and the like are open and the terms indicate the presence of stated structures, elements or features but not preclude the presence of additional elements or features. The articles “a”, “an” and “the” are intended to include the plural as well as the singular, unless the context clearly indicates otherwise.

The skilled person will understand that in the preceding description and appended claims, positional terms such as ‘top’, ‘bottom’, ‘lateral’, ‘vertical’, etc. are made with reference to conceptual illustrations of a semiconductor device, such as those showing standard cross-sectional perspectives and those shown in the appended drawings. These terms are used for ease of reference but are not intended to be of limiting nature. These terms are therefore to be understood as referring to a device when in an orientation as shown in the accompanying drawings.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in the disclosure, whether alone or in any appropriate combination with any other feature disclosed or illustrated herein.

1. A power semiconductor module comprising:
a first substrate;
a second substrate;
a circuit board arranged between the first and second substrates;
a first power semiconductor device comprising first and second power electrodes and arranged between the circuit board and the first substrate; and
a second power semiconductor device comprising third and fourth power electrodes and arranged between the circuit board and the second substrate;
wherein: the circuit board comprises a plurality of electrically conductive layers stacked with a plurality of electrically insulating layers along a stacking direction; at least one of the electrically insulating layers is arranged between adjacent ones of the electrically conductive layers; and the plurality of electrically conductive layers comprises first, second and third electrically conductive layers which are spaced apart from one another along the stacking direction; and
wherein: the first power electrode is electrically connected to the first electrically conductive layer; the second and third power electrodes are both electrically connected to the third electrically conductive layer; and the fourth power electrode is electrically connected to the second electrically conductive layer.

2. The power semiconductor module of claim 1, wherein the second electrically conductive layer is arranged between the first and third electrically conductive layers.

3. The power semiconductor module of claim 2, wherein the first and second electrically conductive layers are separated by a single electrically insulating layer.

4. The power semiconductor module of claim 1, wherein:
the first substrate comprises a first electrically insulating body and a first patterned electrically conductive layer arranged on a surface of the first electrically insulating body that faces the circuit board;
the second substrate comprises a second electrically insulating body and a second patterned electrically conductive layer arranged on a surface of the second electrically insulating body that faces the circuit board;
the first patterned electrically conductive layer comprises a first conductive track electrically connected to the first electrically conductive layer;
the second patterned electrically conductive layer comprises a second conductive track electrically connected to the second electrically conductive layer; and
one of the first and second patterned electrically conductive layers further comprises a third conductive track electrically connected to the third electrically conductive layer.

5. The power semiconductor module of claim 4, further comprising first, second and third power terminals electrically connected to the first, second and third conductive tracks, respectively.

6. (canceled)

7. The power semiconductor module of claim 5, wherein the first and second power terminals are DC input terminals, and the third power terminal is an AC output terminal.

8. The power semiconductor module of claim 4, wherein the first and second conductive tracks have approximately the same area on the respective electrically insulating body.

9. The power semiconductor module of claim 1, wherein:
the first and second power electrodes are both arranged on a surface of the first power semiconductor device that faces the circuit board; and/or
the third and fourth power electrodes are both arranged on a surface of the second power semiconductor device that faces the circuit board.

10. The power semiconductor module of claim 1, wherein the plurality of electrically conductive layers further comprises fourth and fifth electrically conductive layers which are spaced apart from one another along the stacking direction, wherein:
the fourth electrically conductive layer is electrically connected to a first through-layer via of the circuit board, which is further electrically connected to the first electrically conductive layer; and
the fifth electrically conductive layer is electrically connected to a second through-layer via of the circuit board, which is further electrically connected to the second electrically conductive layer.

11. The power semiconductor module of claim 10, wherein the third electrically conductive layer is arranged between the second and fifth electrically conductive layers, which are further arranged between the first and fourth electrically conductive layers.

12. The power semiconductor module of claim 10, wherein the plurality of electrically conductive layers further comprises a sixth electrically conductive layer which is electrically connected to a third through-layer via of the circuit board, and the third through-layer via is further electrically connected to the third electrically conductive layer.

13. The power semiconductor module of claim 4, wherein:
the first patterned electrically conductive layer comprises fourth and fifth conductive tracks which are spaced apart from one another;
the power semiconductor module comprises fourth and fifth control terminals electrically connected to the fourth and fifth conductive tracks, respectively.

14. (canceled)

15. The power semiconductor module of claim 13, wherein:
the first power semiconductor device comprises a first control electrode configured to switch a power current flowing between the first power electrode and the second power electrode;
the plurality of electrically conductive layers further comprises seventh and eighth electrically conductive layers which are spaced apart from one another along the stacking direction;
the first control electrode is electrically connected to the seventh electrically conductive layer, which is further electrically connected to the fourth conductive track; and
the first power electrode is electrically connected to the eighth electrically conductive layer, which is further electrically connected to the fifth conductive track.

16. The power semiconductor module of claim 13, wherein:
the first power semiconductor device comprises a first control electrode configured to switch a power current flowing between the first power electrode and the second power electrode;
the plurality of electrically conductive layers further comprises a seventh electrically conductive layer which is patterned to form two or more conductive tracks, the two or more conductive tracks being spaced apart from one another;
the first control electrode is electrically connected to one conductive track of the seventh electrically conductive layer, which is further electrically connected to the fourth conductive track; and
the first power electrode is electrically connected to another conductive track of the seventh electrically conductive layer, which is further electrically connected to the fifth conductive track.

17. (canceled)

18. The power semiconductor module of claim 1, wherein:
the plurality of electrically conductive layers further comprise: a first patterned interface layer on a first surface of the circuit board that faces the first power semiconductor device; and a second patterned interface layer on a second surface of the circuit board that faces the second power semiconductor device; and
the second surface is opposite to the first surface.

19. The power semiconductor module of any claim 1, further comprising:
a first heat removal structure thermally coupled to the first substrate; and/or
a second heat removal structure thermally coupled to the second substrate.

20. (canceled)

21. The power semiconductor module of claim 1, wherein the circuit board is a flexible circuit board.

22. A method of operating the power semiconductor module of claim 4, comprising: electrically connecting the first and second conductive tracks to a DC power supply.

23. (canceled)

24. A method of manufacturing a power semiconductor module, comprising:
attaching a first power semiconductor device to a first surface of a circuit board, wherein the first power semiconductor device comprises first and second power electrodes, and wherein the circuit board comprises a plurality of electrically conductive layers stacked with a plurality of electrically insulating layers along a stacking direction, at least one of the electrically insulating layers being arranged between adjacent ones of the electrically conductive layers, and wherein the plurality of electrically conductive layers comprises first, second and third electrically conductive layers which are spaced apart from one another along the stacking direction;
attaching a second power semiconductor device to a second surface of the circuit board, wherein the second surface is opposite to the first surface, and the second power semiconductor device comprises third and fourth power electrodes;
mounting the first surface of the circuit board to a first substrate such that the first power semiconductor device is between the circuit board and the first substrate; and
mounting the second surface of the circuit board to a second substrate such that the second power semiconductor device is between the circuit board and the second substrate;
wherein attaching the first power semiconductor device and attaching the second power semiconductor device comprise:
electrically connecting the first power electrode to the first electrically conductive layer;
electrically connecting each of the second and third power electrodes to the third electrically conductive layer; and
electrically connecting the fourth power electrode to the second electrically conductive layer.

25. The method of claim 24, wherein:
the first substrate comprising a first electrically insulating body and a first patterned electrically conductive layer arranged on a surface of the first electrically insulating body that faces the circuit board;
the second substrate comprises a second electrically insulating body and a second patterned electrically conductive layer arranged on a surface of the second electrically insulating body that faces the circuit board;
the first patterned electrically conductive layer comprises a first conductive track;
the second patterned electrically conductive layer comprises a second conductive track;
one of the first and second patterned electrically conductive layers further comprises a third conductive track; and
the method further comprises: mounting first, second and third power terminals directly on the first, second and third conductive tracks, respectively.

26. (canceled)
